(19) United States
(12) Patent Application Publication
(10) Pub. No.: US 2023/0133638 A1
(43) Pub. Date: May 4, 2023

(54) SEMICONDUCTOR DEVICE AND METHOD FOR FABRICATING THE SAME

(71) Applicant: SK hynix Inc., Icheon-si (KR)

(72) Inventor: Tae Jung HA, Icheon-si (KR)

(21) Appl. No.: 17/903,962

(22) Filed: Sep. 6, 2022

(30) Foreign Application Priority Data
Oct. 28, 2021 (KR) 10-2021-0145521

(51) Int. Cl. H01L 45/00; H01L 27/24

(52) U.S. Cl. CPC H01L 45/1666; H01L 27/2481; H01L 45/1253

(57) ABSTRACT

A method for fabricating a semiconductor device may include: forming a first line over a substrate; forming a variable resistance layer on the first line; forming a first dielectric layer on the first line and the variable resistance layer; forming a second dielectric layer on the first dielectric layer; removing a portion of the interlayer dielectric layer to expose a portion of the first dielectric layer; and incorporating a dopant into an exposed portion of the first dielectric layer by performing an ion implantation process to convert the portion of the first dielectric layer into a selector layer.

### PRIORITY CLAIM AND CROSS-REFERENCE TO RELATED APPLICATION

This patent document claims the priority under 35 U.S.C. § 119 to Korean Patent Application No. 10-2021-0145521 filed on Oct. 28, 2021, which is incorporated herein by reference in its entirety.

### TECHNICAL FIELD

The technology and implementations disclosed in this patent document relate to memory circuits or devices and their applications in electronic devices or systems.

### BACKGROUND

Recently, as electronic appliances trend toward miniaturization, low power consumption, high performance, multi-functionality, and so on, semiconductor devices capable of storing information in various electronic appliances such as a computer, a portable communication device, and so on have been demanded in the art, and research has been conducted for the semiconductor devices. Such semiconductor devices can store data by switching between different resistance states according to an applied voltage or current. The semiconductor devices may include an RRAM (resistive random access memory), a PRAM (phase change random access memory), an FRAM (ferroelectric random access memory), an MRAM (magnetic random access memory), an E-fuse, etc.

### SUMMARY

The disclosed technology in this patent document includes memory circuits or devices and their applications in electronic devices or systems and various implementations of an electronic device, in which an electronic device includes a semiconductor device which can reduce process difficulty and ensure scalability.

In one aspect, a semiconductor device may include: a first line; a second line disposed over the first line to be spaced apart from the first line; a variable resistance layer disposed between the first line and the second line; a selector layer interposed between the variable resistance layer and the second line; a first dielectric layer including a dielectric material and disposed on the first line and sidewalls of the variable resistance layer and the selector layer; and a second dielectric layer disposed on the first dielectric layer, wherein the selector layer includes the dielectric material included in the first dielectric layer and a dopant doped in the dielectric material.

In another aspect, a method for fabricating a semiconductor device may include: forming a first line over a substrate; forming a variable resistance layer on the first line; forming a first dielectric layer on the first line and the variable resistance layer; forming a second dielectric layer on the first dielectric layer; removing a portion of the interlayer dielectric layer to expose a portion of the first dielectric layer; and incorporating a dopant into an exposed portion of the first dielectric layer by performing an ion implantation process to convert the portion of the first dielectric layer into a selector layer.

### BRIEF DESCRIPTION OF THE DRAWINGS

FIGS. 1A and 1B illustrate a semiconductor device based on some implementations of the disclosed technology.

FIG. 1C illustrates an example of Magnetic Tunnel Junction (MTJ) structure included in a variable resistance layer based on some implementations of the disclosed technology.

FIGS. 2A to 2F are cross-sectional views illustrating an example method for fabricating a semiconductor device based on some implementations of the disclosed technology.

FIG. 3 illustrates another example of a semiconductor device based on some implementations of the disclosed technology.

FIG. 4 illustrates still another example of a semiconductor device based on some implementations of the disclosed technology.

### DETAILED DESCRIPTION

Hereinafter, various embodiments of the disclosure will be described in detail with reference to the accompanying drawings.

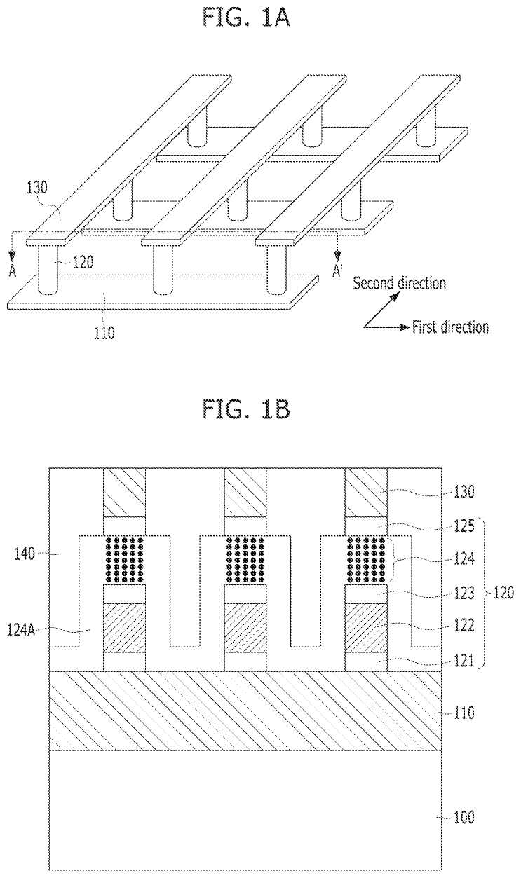

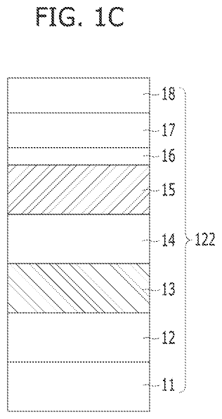

FIGS. 1A and 1B illustrate a semiconductor device based on some implementations of the disclosed technology. FIG. 1A is a perspective view, and FIG. 1B is a cross-sectional view taken along line A-A′ of FIG. 1A.

Referring to FIGS. 1A and 1B, the semiconductor device may include a cross-point structure including a substrate 100, first lines 110 formed over the substrate 100 and extending in a first direction, second lines 130 formed over the first lines 110 to be spaced apart from the first lines 110 and extending in a second direction crossing the first direction, and memory cells 120 disposed at intersections of the first lines 110 and the second lines 130 between the first lines 110 and the second lines 130.

The substrate 100 may include a semiconductor material such as silicon. A required lower structure (not shown) may be formed in the substrate 100. For example, the substrate 100 may include a driving circuit (not shown) electrically connected to the first lines 110 and/or the second lines 130 to control operations of the memory cells 120.

The first line 110 and the second line 130 may be connected to a lower end and an upper end of the memory cell 120, respectively, and may provide a voltage or a current to the memory cell 120 to drive the memory cell 120. When the first line 110 functions as a word line, the second line 130 may function as a bit line. Conversely, when the first line 110 functions as a bit line, the second line 130 may function as a word line. The first line 110 and the second line 130 may include a single-layer or multilayer structure including one or more of various conductive materials. Examples of the conductive materials may include a metal, a metal nitride, or a conductive carbon material, or a combination thereof, but are not limited thereto. For example, the first line 110 and the second line 130 may include tungsten (W), titanium (Ti), tantalum (Ta), platinum (Pt), aluminum (Al), copper (Cu), zinc (Zn), nickel (Ni), cobalt (Co), lead (Pb), tungsten nitride (WN), tungsten silicide (WSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), carbon (C), silicon carbide (SiC), or silicon carbon nitride (SiCN), or a combination thereof.

The memory cell 120 may be arranged in a matrix having rows and columns along the first direction and the second direction so as to overlap the intersection regions between the first lines 110 and the second lines 130. In an implementation, each of the memory cells 120 may have a size that is substantially equal to or smaller than that of the intersection region between each corresponding pair of the first lines 110 and the second lines 130. In another implementation, each of the memory cells 120 may have a size that is larger than that of the intersection region between each corresponding pair of the first lines 110 and the second lines 130.

Spaces between the first line 110, the second line 130 and the memory cell 120 may be filled with a dielectric material.

The memory cell 120 may include a stacked structure including a lower electrode layer 121, a variable resistance layer 122, a middle electrode layer 123, a selector layer 124, and an upper electrode layer 125.

The lower electrode layer 121 may be interposed between the first line 110 and the variable resistance layer 122 and disposed at a lowermost portion of each of the memory cells 120. The lower electrode layer 121 may function as a circuit node that carries a voltage or a current between a corresponding one of the first lines 110 and the remaining portion (e.g., the elements 122, 123, 124 and 125) of each of the memory cells 120. The middle electrode layer 123 may be interposed between the variable resistance layer 122 and the selector layer 124. The middle electrode layer 123 may electrically connect the variable resistance layer 122 and the selector layer 124 to each other while physically separating the variable resistance layer 122 and the selector layer 124 from each other. The upper electrode layer 125 may be disposed at an uppermost portion of the memory cell 120 and function as a transmission path of a voltage or a current between the rest of the memory cell 120 and a corresponding one of the second lines 130.

The lower electrode layer 121, the middle electrode layer 123 and the upper electrode layer 125 may include a single-layer or multilayer structure including various conductive materials such as a metal, a metal nitride, a conductive carbon material, or a combination thereof, respectively. For example, the lower electrode layer 121, the middle electrode layer 123 and the upper electrode layer 125 may include tungsten (W), titanium (Ti), tantalum (Ta), platinum (Pt), aluminum (Al), copper (Cu), copper (Cu), zinc (Zn), nickel (Ni), cobalt (Co), lead (Pb), tungsten nitride (WN), tungsten silicide (WSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), carbon (C), silicon carbide (SiC), or silicon carbon nitride (SiCN), or a combination thereof.

The lower electrode layer 121, the middle electrode layer 123 and the upper electrode layer 125 may include the same material as each other or different materials from each other.

The lower electrode layer 121, the middle electrode layer 123 and the upper electrode layer 125 may have the same thickness as each other or different thicknesses from each other.

The variable resistance layer 122 may be used to store data using the different resistance states of the variable resistance layer 123 (e.g., using high and low resistance states to represent digital level “1” and “0”) by setting the variable resistance layer 123 into a desired resistance state, and to change a stored data bit by switching between different resistance states according to an applied voltage or current. The variable resistance layer 122 may have a single-layered structure or a multi-layered structure including at least one of materials used for an RRAM, a PRAM, an MRAM, an FRAM, or others. For example, the variable resistance layer 122 may include a metal oxide such as a transition metal oxide or a perovskite-based oxide, a phase change material such as a chalcogenide-based material, a ferromagnetic material, a ferroelectric material, or others. Although the variable resistance layer 122 is described in this implementation, other implementations are also possible. For example, the memory cell 120 may include other memory layers capable of storing data in various ways without being limited to the variable resistance layer 122.

In some implementations, the variable resistance layer 122 may include a magnetic tunnel junction (MTJ) structure. This will be explained with reference to FIG. 1C.

FIG. 1C illustrates an example of Magnetic Tunnel Junction (MTJ) structure included in the variable resistance layer 122.

The variable resistance layer 122 may include an MTJ structure including a free layer 13 having a variable magnetization direction, a pinned layer 15 having a pinned magnetization direction and a tunnel barrier layer 14 interposed between the free layer 13 and the pinned layer 15.

The free layer 13 may have one of different magnetization directions or one of different spin directions of electrons to switch the polarity of the free layer 13 in the MTJ structure, resulting in changes in resistance value. In some implementations, the polarity of the free layer 13 is changed or flipped upon application of a voltage or current signal (e.g., a driving current above a certain threshold) to the MTJ structure. With the polarity changes of the free layer 13, the free layer 13 and the pinned layer 15 have different magnetization directions or different spin directions of electron, which allows the variable resistance layer 122 to store different data or represent different data bits. The free layer 13 may also be referred as a storage layer. The magnetization direction of the free layer 13 may be substantially perpendicular to a surface of the free layer 13, the tunnel barrier layer 14 and the pinned layer 15. In other words, the magnetization direction of the free layer 13 may be substantially parallel to stacking directions of the free layer 13, the tunnel barrier layer 14 and the pinned layer 15. Therefore, the magnetization direction of the free layer 13 may be changed between a downward direction and an upward direction. The change in the magnetization direction of the free layer 13 may be induced by a spin transfer torque generated by an applied current or voltage.

The free layer 13 may have a single-layer or multilayer structure including a ferromagnetic material. For example, the free layer 13 may include an alloy based on Fe, Ni or Co, for example, an Fe—Pt alloy, an Fe—Pd alloy, a Co—Pd alloy, a Co—Pt alloy, a Co—Fe alloy, an Fe—Ni—Pt alloy, a Co—Fe—Pt alloy, a Co—Ni—Pt alloy, or a Co—Fe—B alloy, or others, or may include a stack of metals, such as Co/Pt, or Co/Pd, or others.

The tunnel barrier layer 14 may allow the tunneling of electrons in both data reading and data writing operations. In a write operation for storing new data, a high write current may be directed through the tunnel barrier layer 14 to change the magnetization direction of the free layer 13 and thus to change the resistance state of the MTJ for writing a new data bit. In a reading operation, a low reading current may be directed through the tunnel barrier layer 14 without changing the magnetization direction of the free layer 13 to measure the existing resistance state of the MTJ under the existing magnetization direction of the free layer 13 to read the stored data bit in the MTJ. The tunnel barrier layer 14 may include a dielectric oxide such as MgO, CaO, SrO, TiO, VO, or NbO or others.

The pinned layer 15 may have a pinned magnetization direction, which remains unchanged while the magnetization direction of the free layer 13 changes. The pinned layer 15 may be referred to as a reference layer. In some implementations, the magnetization direction of the pinned layer 15 may be pinned in a downward direction. In some implementations, the magnetization direction of the pinned layer 15 may be pinned in an upward direction.

The pinned layer 15 may have a single-layer or multilayer structure including a ferromagnetic material. For example, the pinned layer 15 may include an alloy based on Fe, Ni or Co, for example, an Fe—Pt alloy, an Fe—Pd alloy, a Co—Pd alloy, a Co—Pt alloy, a Co—Fe alloy, an Fe—Ni—Pt alloy, a Co—Fe—Pt alloy, a Co—Ni—Pt alloy, or a Co—Fe—B alloy, or may include a stack of metals, such as Co/Pt, or Co/Pd or others.

If a voltage or current is applied to the variable resistance layer 122, the magnetization direction of the free layer 13 may be changed by spin torque transfer. In some implementations, when the magnetization directions of the free layer 13 and the pinned layer 15 are parallel to each other, the variable resistance layer 122 may be in a low resistance state, and this may indicate digital data bit “0.” Conversely, when the magnetization directions of the free layer 13 and the pinned layer 15 are anti-parallel to each other, the variable resistance layer 122 may be in a high resistance state, and this may indicate a digital data bit “1.” In some implementations, the variable resistance layer 122 can be configured to store data bit ‘1’ when the magnetization directions of the free layer 13 and the pinned layer 15 are parallel to each other and to store data bit ‘0’ when the magnetization directions of the free layer 13 and the pinned layer 15 are anti-parallel to each other.

In some implementations, the variable resistance layer 122 may further include one or more layers performing various functions to improve a characteristic of the MTJ structure. For example, the variable resistance layer 122 may further include at least one of a buffer layer 11, an under layer 12, a spacer layer 16, a magnetic correction layer 17 and a capping layer 18.

The under layer 12 may be disposed under the free layer 13 and serve to improve perpendicular magnetic crystalline anisotropy of the free layer 13. The under layer 12 may have a single-layer or multilayer structure including a metal, a metal alloy, a metal nitride, or a metal oxide, or a combination thereof.

The buffer layer 11 may be disposed below the under layer 12 to facilitate crystal growth of the under layer 12, thus improving perpendicular magnetic crystalline anisotropy of the free layer 13. The buffer layer 11 may have a single-layer or multilayer structure including a metal, a metal alloy, a metal nitride, or a metal oxide, or a combination thereof. Moreover, the buffer layer 11 may be formed of or include a material having a good compatibility with a bottom electrode (not shown) in order to resolve the lattice constant mismatch between the bottom electrode and the under layer 12. For example, the buffer layer 11 may include tantalum (Ta).

The spacer layer 16 may be interposed between the magnetic correction layer 17 and the pinned layer 15 and function as a buffer between the magnetic correction layer 17 and the pinned layer 15. The spacer layer 16 may serve to improve characteristics of the magnetic correction layer 17. The spacer layer 16 may include a noble metal such as ruthenium (Ru).

The magnetic correction layer 17 may serve to offset the effect of the stray magnetic field produced by the pinned layer 15. In this case, the effect of the stray magnetic field of the pinned layer 15 can decrease, and thus a biased magnetic field in the free layer 13 can decrease. The magnetic correction layer 17 may have a magnetization direction anti-parallel to the magnetization direction of the pinned layer 15. In the implementation, when the pinned layer 15 has a downward magnetization direction, the magnetic correction layer 17 may have an upward magnetization direction. Conversely, when the pinned layer 15 has an upward magnetization direction, the magnetic correction layer 17 may have a downward magnetization direction. The magnetic correction layer 17 may be exchange coupled with the pinned layer 15 via the spacer layer 16 to form a synthetic anti-ferromagnet (SAF) structure. The magnetic correction layer 17 may have a single-layer or multilayer structure including a ferromagnetic material.

In this implementation, the magnetic correction layer 17 is located above the pinned layer 15, but the magnetic correction layer 17 may disposed at a different location. For example, the magnetic correction layer 17 may be located above, below, or next to the MTJ structure while the magnetic correction layer 17 is patterned separately from the MTJ structure.

The capping layer 18 may serve to protect the variable resistance layer 122 and/or function as a hard mask for patterning the variable resistance layer 122. In some implementations, the capping layer 18 may include various conductive materials such as a metal. In some implementations, the capping layer 18 may include a metallic material having almost none or a small number of pin holes and high resistance to wet and/or dry etching. In some implementations, the capping layer 18 may include a metal, a nitride, or an oxide, or a combination thereof. For example, the capping layer 18 may include a noble metal such as ruthenium (Ru).

The capping layer 18 may have a single-layer or multilayer structure. In some implementations, the capping layer 18 may have a multilayer structure including an oxide, or a metal, or a combination thereof. For example, the capping layer 18 may have a multilayer structure of an oxide layer, a first metal layer and a second metal layer.

A material layer (not shown) for resolving the lattice structure differences and the lattice constant mismatch between the pinned layer 15 and the magnetic correction layer 17 may be interposed between the pinned layer 15 and the magnetic correction layer 17. For example, this material layer may be amorphous and may include a metal a metal nitride, or metal oxide.

The selector layer 124 may serve to control access to the variable resistance layer 122. To this end, the selector layer 124 may control the flow of a current according to the magnitude of the voltage or a current applied to the selector layer 124. For example, the selection element 124 may block or substantially limit a current flowing through the memory cell 120 when a magnitude of an applied voltage is less than a predetermined threshold value and allow a current flowing through the memory cell 120 to abruptly increase when the magnitude of the applied voltage is equal to or greater than the threshold value. In some implementations, the selector layer 124 may include an MIT (Metal Insulator Transition) material such as NbO₂, TiO₂, VO₂, WO₂, or others. In some implementations, the selector layer 124 may include an MIEC (Mixed Ion-Electron Conducting) material such as ZrO₂(Y₂O₃), Bi₂O₃—BaO, (La₂O₃)ₓ(CeO₂)₁₋ₓ, or others. In some implementations, the selector layer 124 may include an OTS (Ovonic Threshold Switching) material including chalcogenide material such as Ge₂Sb₂Te₅, As₂Te₃, As₂, As₂Se₃, or others. In some implementations, the selector layer 124 may include a tunneling insulating material such as silicon oxide, silicon nitride, a metal oxide, or others. A thickness of the tunneling insulating layer is sufficiently small to allow the tunneling of electrons under a given voltage or a given current. The selector layer 124 may include a single-layer or multilayer structure.

In one implementation, the selector layer 124 may be configured to perform a threshold switching operation. The term “threshold switching operation” may indicate the operation to turn on or off the selector layer 124 while an external voltage is applied to the selector layer 124. The absolute value of the external voltage may gradually increase or decrease. When the absolute value of the external voltage applied to the selector layer 124 increases, the selector layer 124 may be turned on to be electrically conductive to allow a current follow through when the absolute value of the external voltage is greater than a first threshold voltage. Once the selector layer 124 is turned on, the increase of the external voltage causes an operation current flowing therethrough to increase nonlinearly. When the absolute value of the external voltage applied to the selector layer 124 decreases after the selector layer 124 is turned on, selector layer the operation current flowing through the selector layer 124 decreases nonlinearly. When the absolute value of the external voltage applied the selector layer 124 decreases further to a low voltage value that is less than a second threshold voltage, the selector layer 124 become electrically non conductive and the operation current flowing through the selector layer 124 is turned off. As such, the selector layer 124 performing the threshold switching operation may have a non-memory operation characteristic.

In some implementations, the selector layer 124 may include a doped dielectric material having dopants. The selector layer 124 may include an oxide with dopants, a nitride with dopants, or an oxynitride with dopants, or a combination thereof such as silicon oxide, titanium oxide, aluminum oxide, tungsten oxide, hafnium oxide, tantalum oxide, niobium oxide, silicon nitride, titanium nitride, aluminum nitride, tungsten nitride, hafnium nitride, tantalum nitride, niobium nitride, silicon oxynitride, titanium oxynitride, aluminum oxynitride, tungsten oxynitride, hafnium oxynitride, tantalum oxynitride, or niobium oxynitride, or a combination thereof. The dopants doped into the selector layer 124 may include an n-type dopant or a p-type dopant and be incorporated for example, by ion implantation process. Examples of the dopants may include one or more of boron (B), nitrogen (N), carbon (C), phosphorous (P), arsenic (As), aluminum (Al), silicon (Si) and germanium (Ge). For example, the selector layer 124 may include As-doped silicon oxide or Ge-doped silicon oxide.

To form a high-density cross-point array, the variable resistance layer 122 and the selector layer 124 have been usually formed on an upper portion and a lower portion of the same element. The variable resistance layer 122 and the selector layer 124 may be formed by depositing materials layer for forming the variable resistance layer 122 and the selector layer 124 and etching the material layers by performing patterning processes. In this case, the variable resistance layer 122 may be etched by IBE (Ion Beam Etch), while the selector layer 124 may be etched by an RIE (Reactive Ion Etch). Since the etching methods for the variable resistance layer 122 and the selector layer 124 are different from each other, a separate passivation process is required to protect one of the variable resistance layer 122 and the selector layer 124 while the other one of the variable resistance layer 122 and the selector layer 124 is being etched. However, it is difficult to select a material and a process suitable for both the variable resistance layer 122 and the selector layer 124. Therefore, a lot of resources are required for the integration process and the process becomes complicated. Despite the complicated integration process, integration damage to each device is more accumulated and a process margin becomes decreased. As a result, there is a great difficulty in expanding into a large array and scaling down.

In order to overcome these problems, in implementations of the disclosed technology, the selector layer 124 may be formed through a self-alignment method by performing an ion implantation process during patterning an upper part of the memory cell 120, instead of performing a separate patterning process. In accordance with the implementations, since the patterning process may be performed only on the variable resistance layer 122 before forming the selector layer 124 and there is no patterning process for the selector layer 124, damage to the selector layer 124 can be avoided when patterning the variable resistance layer 122 and damage to the variable resistance layer 122 can be prevented during the forming of the selector layer 124. Moreover, since the patterning process is performed on the variable resistance layer 122 only, the passivation process can be performed by selecting an appropriate material and process in consideration of the variable resistance layer 122 only without the need to consider the selector layer 124.

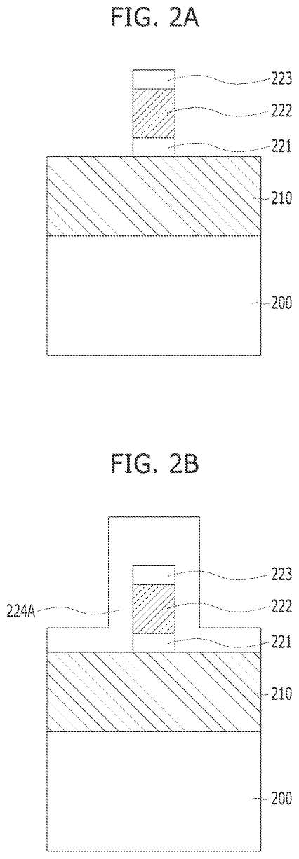

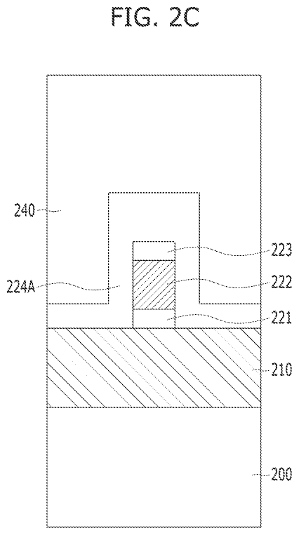

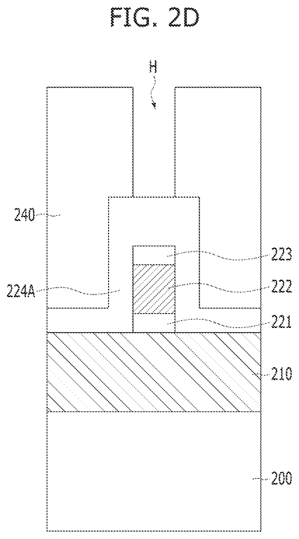

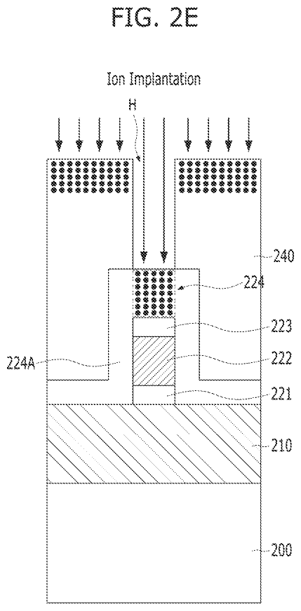

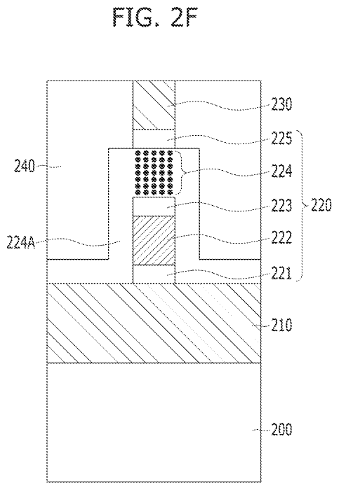

The process for forming the selector layer 124 may be described in detail later in this patent document with reference to FIGS. 2A to 2F.

In some implementations, the selector layer 124 may perform a threshold switching operation through a doped region formed in a material layer for the selector layer 124. Thus, a size of the threshold switching operation region may be controlled by a distribution area of the dopants. The dopants may form trap sites for charge carriers in the material layer for the selector layer 124. The trap sites may capture the charge carriers moving in the selector layer 124, based on an external voltage applied to the selector layer 124. The trap sites thereby provide a threshold switching characteristic and are used to perform a threshold switching operation.

A selection element matrix layer 124A may be disposed between the first lines 110, the lower electrode layer 121, the variable resistance layer 122, the middle electrode layer 123 and the selector layer 124, and the interlayer dielectric layer 140. Thus, the selection element matrix layer 124A may be formed on an exposed upper surface of the first lines 110 and sidewalls of the lower electrode layer 121, the variable resistance layer 122, the middle electrode layer 123 and the selector layer 124.

The selection element matrix layer 124A may include a dielectric layer. For example, the selection element matrix layer 124A may include an oxide, a nitride, an oxynitride, or a combination thereof. Examples of the oxide, the nitride and/or the oxynitride may include silicon oxide, tungsten oxide, titanium oxide, vanadium oxide, chromium oxide, platinum oxide, aluminum oxide, copper oxide, zinc oxide, nickel oxide, cobalt oxide, lead oxide, manganese oxide, niobium oxide, hafnium oxide, silicon nitride, tungsten nitride, titanium nitride, vanadium nitride, chromium nitride, platinum nitride, aluminum nitride, copper nitride, zinc nitride, nickel nitride, cobalt nitride, lead nitride, manganese nitride, niobium nitride, hafnium nitride, silicon oxynitride, tungsten oxynitride, titanium oxynitride, vanadium oxynitride, chromium oxynitride, Platinum oxynitride, aluminum oxynitride, copper oxynitride, zinc oxynitride, nickel oxynitride, cobalt oxynitride, lead oxynitride, manganese oxynitride, niobium oxynitride, or hafnium oxynitride, or a combination thereof.

In some implementations, each of the memory cell 120 may include the lower electrode layer 121, the variable resistance layer 122, the middle electrode layer 123, the selector layer 124, and the upper electrode layer 125 which are sequentially stacked. However, the memory cells 120 may have different structures. In some implementations, at least one of the lower electrode layer 121, the middle electrode layer 123 and the upper electrode layer 125 may be omitted. In some implementations, in addition to the layers 121 to 125 shown in FIG. 1B, the memory cells 120 may further include one or more layers (not shown) for enhancing characteristics of the memory cells 120 or improving fabricating processes.

In some implementations, neighboring memory cells of the plurality of memory cells 120 may be spaced apart from each other at a predetermined interval, and trenches may be present between the plurality of memory cells 120. A trench between neighboring memory cells 120 may have a height to width ratio (i.e., an aspect ratio) in a range from 1:1 to 40:1, from 10:1 to 40:1, from 10:1 to 20:1, from 5:1 to 10:1, from 10:1 to 15:1, from 1:1 to 25:1, from 1:1 to 30:1, from 1:1 to 35:1, or from 1:1 to 45:1.

In some implementations, the trench may have sidewalls that are substantially perpendicular to an upper surface of the substrate 100. In some implementations, neighboring trenches may be spaced apart from each other by an equal or similar distance.

In some implementations, the semiconductor device may include further layers in addition to the first line 110, the memory cell 120 and the second line 130. For example, a lower electrode contact may be further formed between the first line 110 and the lower electrode layer 121 and an upper electrode contact may be further formed between the second line 130 and the upper electrode layer 125.

Although one cross-point structure has been described, two or more cross-point structures may be stacked in a vertical direction perpendicular to a top surface of the substrate 100.

The memory cell 120 may include the variable resistance layer 122 formed by a separate patterning process and the selector layer 124 formed by a self-alignment method instead of performing a separate patterning process. The selector layer 124 may include a dielectric layer having a dopant.

A method for fabricating a semiconductor device will be explained with reference to FIGS. 2A to 2F.

Referring to FIG. 2A, first lines 210 may be formed over a substrate 200 in which a predetermined structure is formed. The first lines 210 may be formed by forming a first interlayer dielectric layer 301 having a trench for forming the first lines 210 over the substrate 200, forming a conductive layer for the first lines 210, and etching the conductive layer using a mask pattern in a line shape extending in a first direction.

Then, a lower electrode layer 221, a variable resistance layer 222 and a middle electrode layer 223 may be formed over the first lines 210. The lower electrode layer 221, the variable resistance layer 222 and the middle electrode layer 223 may be formed by forming material layers for forming the lower electrode layer 221, the variable resistance layer 222 and the middle electrode layer 223 and etching the material layers by using a hard mask pattern.

In accordance with the implementations, since a patterning process for forming the variable resistance layer 222 is performed before forming the selector layer (see, reference numeral 224 of FIG. 2E), integration damage to the selector layer 224 formed in a subsequent process can be avoided. Moreover, when patterning the variable resistance layer 222, since there is no need to consider the selector layer 224, it is possible to select a more suitable process for the variable resistance layer 222 by only considering the characteristics of the variable resistance layer 222.

Referring to FIG. 2B, a selection element matrix layer 224A for forming the selector layer 224 may be formed on the structure of FIG. 2A.

The selection element matrix layer 224A may be a layer capable of forming the selector layer 224 by incorporating a dopant into the selection element matrix layer 224A by an ion implantation process.

The selection element matrix layer 224A may be conformally formed on the structure of FIG. 2A so that the selection element matrix layer 224A may be formed to cover the exposed first lines 210, the lower electrode layer 221, the variable resistance layer 222 and the middle electrode layer 223.

The selection element matrix layer 224A may include a dielectric layer. For example, the selection element matrix layer 224A may include an oxide, a nitride, an oxynitride, or a combination thereof. Examples of the oxide, the nitride and/or the oxynitride may include silicon oxide, tungsten oxide, titanium oxide, vanadium oxide, chromium oxide, platinum oxide, aluminum oxide, copper oxide, zinc oxide, nickel oxide, cobalt oxide, lead oxide, manganese oxide, niobium oxide, hafnium oxide, silicon nitride, tungsten nitride, titanium nitride, vanadium nitride, chromium nitride, platinum nitride, aluminum nitride, copper nitride, zinc nitride, nickel nitride, cobalt nitride, lead nitride, manganese nitride, niobium nitride, hafnium nitride, silicon oxynitride, tungsten oxynitride, titanium oxynitride, vanadium oxynitride, chromium oxynitride, Platinum oxynitride, aluminum oxynitride, copper oxynitride, zinc oxynitride, nickel oxynitride, cobalt oxynitride, lead oxynitride, manganese oxynitride, niobium oxynitride, or hafnium oxynitride, or a combination thereof.

A portion of the selection element matrix layer 224A, which is disposed over the middle electrode layer 223, may be a portion capable of forming the selector layer 224 by a self-alignment method through an ion implantation process. Accordingly, a thickness of the portion of the selection element matrix layer 224A may be determined to correspond to a thickness of the selector layer 224.

Referring to FIG. 2C, an interlayer dielectric layer 240 may be formed over the selection element matrix layer 224A.

A thickness of a portion of the interlayer dielectric layer 240 over the selection element matrix layer 224A over the middle electrode layer 223 may be determined to correspond to a thickness of second lines (see, reference numeral 230 of FIG. 2F) formed in a hole (see, reference numeral H of FIG. 2D) in a subsequent process. While it is described as a hole, other implementations are also possible. For example, an empty space with various shapes can be provided instead of the hole by removing a portion of the interlayer dielectric layer. The descriptions on the structures related to the hole can be similarly applied to the empty space provided in the interlayer dielectric layer.

The interlayer dielectric layer 240 and the selection element matrix layer 224A may be formed of the same material as each other, or different materials from each other.

Referring to FIG. 2D. the hole H may be formed in the interlayer dielectric layer 240.

Referring to FIG. 2E, an ion implantation process may be performed on the structure of FIG. 2D. Through the ion implantation process, a dopant may be incorporated into upper portions of the interlayer dielectric layer 240 on both sides of the hole H and a portion of the selection element matrix layer 224A disposed below the hole H. The portion of the selection element matrix layer 224A disposed below the hole H may be converted into the selector layer 224 including the dielectric material and the dopant by a self-alignment method.

Since the selector layer 224 may be formed by ion implantation and self-aligning without an additional patterning process, an interface between the selector layer 224 and the selection element matrix layer 224A may be an interface that is separated depending on the presence or absence of the dopant, not an interface that is physically separated by etching.

The dopant incorporated by the ion implantation process may include one or more of boron (B), nitrogen (N), carbon (C), phosphorous (P), arsenic (As), aluminum (Al), silicon (Si), or germanium (Ge).

In accordance with the implementations of the disclosed technology, since the selector layer 224 is formed without a patterning process using a separate mask, it is possible to prevent damage to the variable resistance layer 222.

Referring to FIG. 2F, a conductive layer for an upper electrode layer 225 and a conductive layer for second lines 230 may be formed in the hole H.

Then, a planarization process such as a CMP (Chemical Mechanical Planarization) process may be performed to remove the doped upper portions of the interlayer dielectric layer 240.

Through the processes as described above, the semiconductor device illustrated in FIG. 2F may be formed. The semiconductor device may include the first lines 210, the lower electrode layer 221, the variable resistance layer 222, the middle electrode layer 223, the selector layer 224, the upper electrode layer 225, and the second lines 230 which are sequentially stacked over the substrate 200. The variable resistance layer 222 may be formed by the patterning process using a separate mask, and the selector layer 224 may be formed by the self-alignment method without performing a separate patterning process. The second lines 230 may be formed in the hole in the interlayer dielectric layer 240 over the selector layer 224. The selection element matrix layer 224A may remain on the exposed upper portion of the first lines 210, and sidewalls of the lower electrode layer 221, the variable resistance layer 222, the middle electrode layer 223 and the selector layer 224.

The semiconductor device described above may include the lower electrode layer 221, the middle electrode layer 223 and the upper electrode layer 225. In some implementations, at least one of the lower electrode layer 221, the middle electrode layer 223 and the upper electrode layer 225 may be omitted.

The substrate 200, the first lines 210, the lower electrode layer 221, the variable resistance layer 222, the middle electrode layer 223, the selector layer 224, the upper electrode layer 225, the second lines 230, the selection element matrix layer 224A and the interlayer dielectric layer 240 illustrated in FIG. 2F may correspond to the substrate 100, the first lines 110, the lower electrode layer 121, the variable resistance layer 122, the middle electrode layer 123, the selector layer 124, the upper electrode layer 125, the second lines 130, the selection element matrix layer 124A and the interlayer dielectric layer 140 illustrated in FIG. 1B, respectively.

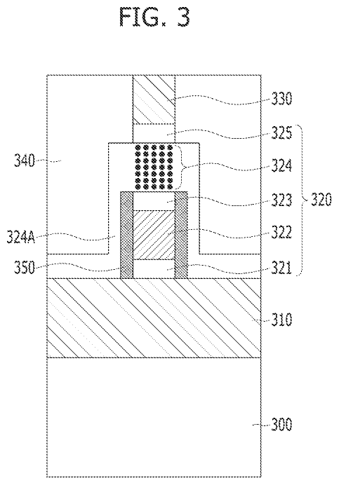

FIG. 3 illustrates another example of a semiconductor device based on some implementations of the disclosed technology.

The semiconductor device illustrated in FIG. 3 is similar to the semiconductor device illustrated in FIGS. 2A to 2F except that a sidewall spacer layer 350 is further included on sidewalls of an electrode layer 321, a variable resistance layer 322 and a middle electrode layer 323. The implementations illustrated in FIG. 3 will be described focusing on differences from the above-described implementations illustrated in FIGS. 2A to 2F.

The semiconductor device may include first lines 310, the lower electrode layer 321, the variable resistance layer 322, the middle electrode layer 323, a selector layer 324, an upper electrode layer 325, second lines 330, a selection element matrix layer 324A, an interlayer dielectric layer 340 and the sidewall spacer layer 350.

The method for fabricating the semiconductor device illustrated in FIG. 3 will be described below.

In a process similar to that illustrated in FIG. 2A, the first lines 310, the lower electrode layer 321, the variable resistance layer 322 and the middle electrode layer 323 may be formed over a substrate 300.

Then, the sidewall spacer layer 350 may be formed on sidewalls of the lower electrode layer 321, the variable resistance layer 322 and the middle electrode layer 323. The sidewall spacer layer 350 may serve to protect the lower electrode layer 321, the variable resistance layer 322 and the middle electrode layer 323 in a subsequent process.

The sidewall spacer layer 350 may be formed of a suitable material depending on material layers for forming the variable resistance layer 322. For example, the sidewall spacer layer 350 may include an oxide, a nitride, or a combination thereof.

Thereafter, subsequent processes may be similar to those illustrated in FIGS. 2A to 2F.

The substrate 300, the first lines 310, the lower electrode layer 321, the variable resistance layer 322, the middle electrode layer 323, the selector layer 324, the upper electrode layer 325, the second lines 330, the selection element matrix layer 324A and the interlayer dielectric layer 340 illustrated in FIG. 3 may correspond to the substrate 100, the first lines 110, the lower electrode layer 121, the variable resistance layer 122, the middle electrode layer 123, the selector layer 124, the upper electrode layer 125, the second lines 130, the selection element matrix layer 124A and the interlayer dielectric layer 140 illustrated in FIG. 1B, respectively, and the substrate 200, the first lines 210, the lower electrode layer 221, the variable resistance layer 222, the middle electrode layer 223, the selector layer 224, the upper electrode layer 225, the second lines 230, the selection element matrix layer 224A and the interlayer dielectric layer 240 illustrated in FIG. 2F, respectively.

In accordance with the implementations, since the variable resistance layer 322 may be formed by a patterning process for the variable resistance layer 322 and then the selector layer 324 may be formed by a self-align method without using a patterning process, a material and a process for forming the sidewall spacer layer 350 may be more suitably selected based on characteristics of the variable resistance layer 322 without considering the selector layer 324. Thus, it is possible to improve protection effect for the variable resistance layer 322 and increase process efficiency.

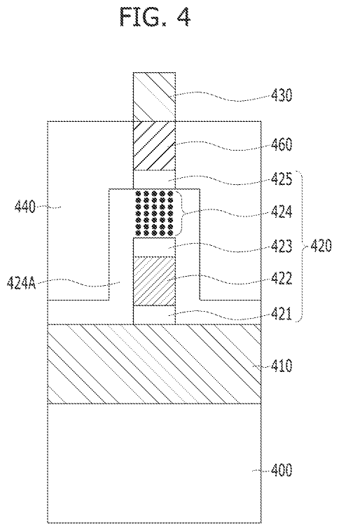

FIG. 4 illustrates still another example of a semiconductor device based on some implementations of the disclosed technology.

The semiconductor device illustrated in FIG. 4 is similar to the semiconductor device illustrated in FIGS. 2A to 2F except that an upper electrode 425 and a contact layer 460 may be formed in a hole in an interlayer dielectric layer 440 and second lines 430 may be formed over the contact layer 460. The implementations illustrated in FIG. 4 will be described focusing on differences from the above-described implementations illustrated in FIGS. 2A to 2F.

The semiconductor device may include first lines 410, a lower electrode layer 421, a variable resistance layer 422, a middle electrode layer 423, a selector layer 424, the upper electrode layer 325, the contact layer 460, the second lines 330, a selection element matrix layer 424A and the interlayer dielectric layer 440.

The method for fabricating the semiconductor device illustrated in FIG. 4 will be described below.

In processes similar to those illustrated in FIGS. 2A to 2E, the first lines 410, the lower electrode layer 421, the variable resistance layer 422, the middle electrode layer 423 and the selector layer 424 may be formed over a substrate 200

The upper electrode layer 425 and the contact layer 460 may be formed in the hole in the interlayer dielectric layer 440.

Then, a planarization process such as a CMP process may be performed on the interlayer dielectric layer 440 to remove an upper portion of the interlayer dielectric layer 440 in which a dopant is incorporated.

For example, the contact layer 460 may include a metal. For example, the contact layer 460 may include at least one of tungsten (W), titanium (Ti), vanadium (V), chromium (Cr), manganese (Mn), iron (Fe), cobalt (Co), nickel (Ni), copper (Cu), niobium (Nb), titanium nitride (TiN), or tantalum nitride (TaN), or a combination thereof.

The second lines 430 may be formed over the contact layer 460.

The substrate 400, the first lines 410, the lower electrode layer 421, the variable resistance layer 422, the middle electrode layer 423, the selector layer 424, the upper electrode layer 425, the second lines 430, the selection element matrix layer 424A and the interlayer dielectric layer 440 illustrated in FIG. 4 may correspond to the substrate 100, the first lines 110, the lower electrode layer 121, the variable resistance layer 122, the middle electrode layer 123, the selector layer 124, the upper electrode layer 125, the second lines 130, the selection element matrix layer 124A and the interlayer dielectric layer 140 illustrated in FIG. 1B, respectively, the substrate 200, the first lines 210, the lower electrode layer 221, the variable resistance layer 222, the middle electrode layer 223, the selector layer 224, the upper electrode layer 225, the second lines 230, the selection element matrix layer 224A and the interlayer dielectric layer 240 illustrated in FIG. 2F, respectively, and the substrate 300, the first lines 310, the lower electrode layer 321, the variable resistance layer 322, the middle electrode layer 323, the selector layer 324, the upper electrode layer 325, the second lines 330, the selection element matrix layer 324A and the interlayer dielectric layer 340 illustrated in FIG. 3, respectively.

While this patent document contains many specifics, these should not be construed as limitations on the scope of any disclosure or of what may be claimed, but rather as descriptions of features that may be specific to particular embodiments of particular disclosures. Certain features that are described in this patent document in the context of separate embodiments can also be implemented in combination in a single embodiment. Conversely, various features that are described in the context of a single embodiment can also be implemented in multiple embodiments separately or in any suitable sub combination. Moreover, although features may be described above as acting in certain combinations and even initially claimed as such, one or more features from a claimed combination can in some cases be excised from the combination, and the claimed combination may be directed to a sub combination or variation of a sub combination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few embodiments and examples are described. Enhancements and variations of the disclosed embodiments and other embodiments can be made based on what is described and illustrated in this patent document.

What is claimed is:

1. A method for fabricating a semiconductor device comprising:
forming a first line over a substrate;
forming a variable resistance layer on the first line;
forming a first dielectric layer on the first line and the variable resistance layer;
forming a second dielectric layer on the first dielectric layer;
removing a portion of the interlayer dielectric layer to expose a portion of the first dielectric layer; and
incorporating a dopant into an exposed portion of the first dielectric layer by performing an ion implantation process to convert the portion of the first dielectric layer into a selector layer.

2. The method according to claim 1, wherein the first dielectric layer includes an oxide, a nitride, an oxynitride, or a combination thereof.

3. The method according to claim 1, wherein the dopant incorporated by the ion implantation process includes one or more of boron (B), nitrogen (N), carbon (C), phosphorous (P), arsenic (As), aluminum (Al), silicon (Si), or germanium (Ge).

4. The method according to claim 1, further comprising forming a second line disposed over the selector layer.

5. The method according to claim 4, further comprising performing a planarization process after the forming of the second line to remove doped portions of the interlayer dielectric layer on both sides of the through-hole.

6. The method according to claim 1, further comprising:
forming a contact layer to be disposed below the second line;
performing a planarization process to remove the doped portions of the interlayer dielectric layer on both sides of the through-hole; and
forming a second line on the contact layer.

7. The method according to claim 1, further comprising forming a sidewall spacer layer on sidewalls of the variable resistance layer.

8. The method according to claim 1, further comprising:
forming a lower electrode layer between the first line and the variable resistance layer;
forming a middle electrode layer between the variable resistance layer and the selector layer; and
forming an upper electrode layer on the selector layer.
